(19) United States
(12) Patent Application Publication
(10) Pub. No.: US 2024/0138071 A1
(43) Pub. Date: Apr. 25, 2024

(54) METHOD FOR MANUFACTURING WIRING SUBSTRATE

(71) Applicant: IBIDEN CO., LTD., Ogaki (JP)

(72) Inventors: Shogo FUKUI, Ogaki (JP); Ryo ANDO, Ogaki (JP); Keisuke SHIMIZU, Ogaki (JP)

(73) Assignee: IBIDEN CO., LTD., Ogaki (JP)

(21) Appl. No.: 18/489,921

(22) Filed: Oct. 18, 2023

(30) Foreign Application Priority Data
Oct. 19, 2022 (JP) 2022-168668

(51) Int. Cl. H05K 1/18; H01L 21/48; H01L 21/56; H01L 23/00; H01L 23/498; H05K 3/00

(52) U.S. Cl. CPC H05K 1/186; H01L 21/4857; H01L 21/4864; H01L 21/56; H01L 23/49822; H01L 24/19; H01L 24/20; H05K 3/0035; H05K 3/0055; H01L 25/0652

(57) ABSTRACT

A method for manufacturing a wiring substrate includes forming conductor pads on a surface of an insulating layer, positioning, on or in the insulating layer, an electronic component having electrode pads, forming a second insulating layer covering the surface of the insulating layer, conductor pads and electronic component, forming first via holes exposing the conductor pads, applying a first desmear treatment to the second insulating layer such that residues are removed from the first via holes, forming second via holes in the second insulating layer after the first desmear treatment such that the second via holes expose the electrode pads of the electronic component positioned on or in the insulating layer, applying a second desmear treatment to the second insulating layer such that residues are removed from the second via holes, forming first via conductors in the first via holes, and forming second via conductors in the second via holes.

### CROSS-REFERENCE TO RELATED APPLICATIONS

The present application is based upon and claims the benefit of priority to Japanese Patent Application No. 2022-168668, filed Oct. 20, 2022, the entire contents of which are incorporated herein by reference.

### BACKGROUND OF THE INVENTION

### Field of the Invention

A technology of the present disclosure relates to a method for manufacturing a wiring substrate.

### DESCRIPTION OF BACKGROUND ART

Japanese Patent Application Laid-Open Publication No. 2016-58472 describes a method for manufacturing a wiring substrate. The entire contents of this publication are incorporated herein by reference.

### SUMMARY OF THE INVENTION

According to one aspect of the present invention, a method for manufacturing a wiring substrate includes forming conductor pads on a surface of an insulating layer, positioning, on or in the insulating layer, an electronic component having electrode pads, forming a second insulating layer on the insulating layer such that the second insulating layer covers the surface of the insulating layer, the conductor pads and the electronic component, forming first via holes in the second insulating layer such that the first via holes expose the conductor pads formed on the surface of the insulating layer, respectively, applying a first desmear treatment to the second insulating layer such that residues are removed from the first via holes formed in the second insulating layer, forming second via holes in the second insulating layer after the first desmear treatment such that the second via holes expose the electrode pads of the electronic component positioned on or in the insulating layer, respectively, applying a second desmear treatment to the second insulating layer such that residues are removed from the second via holes formed in the second insulating layer, forming first via conductors in the first via holes formed in the second insulating layer, respectively, and forming second via conductors in the second via holes formed in the second insulating layer, respectively.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating a wiring substrate according to a first embodiment of the present invention;

FIG. 2 is a partially enlarged cross-sectional view illustrating a wiring substrate according to an embodiment of the present invention;

FIG. 3 is a further partially enlarged cross-sectional view illustrating a wiring substrate according to an embodiment of the present invention;

FIG. 4A is a cross-sectional view illustrating an example of a manufacturing process a wiring substrate according to an embodiment of the present invention;

FIG. 4B is a partially enlarged cross-sectional view illustrating an example of a manufacturing process a wiring substrate according to ant embodiment of the present invention;

FIG. 5A is a cross-sectional view illustrating an example of a manufacturing process of a wiring substrate according to an embodiment of the present invention;

FIG. 5B is a partially enlarged cross-sectional view illustrating an example of a manufacturing process of a wiring substrate according to an embodiment of the present invention;

FIG. 6A is a partially enlarged cross-sectional view illustrating an example of a manufacturing process of a wiring substrate according to an embodiment of the present invention;

FIG. 6B is a partially enlarged cross-sectional view illustrating an example of a manufacturing process of a wiring substrate according to an embodiment of the present invention;

FIG. 6C is a partially enlarged cross-sectional view illustrating an example of a manufacturing process of a wiring substrate according to an embodiment of the present invention;

FIG. 6D is a partially enlarged cross-sectional view illustrating an example of a manufacturing process of a wiring substrate according to an embodiment of the present invention;

FIG. 6E is a partially enlarged cross-sectional view illustrating an example of a manufacturing process of a wiring substrate according to an embodiment of the present invention;

FIG. 6F is a partially enlarged cross-sectional view illustrating an example of a manufacturing process of a wiring substrate according to an embodiment of the present invention;

FIG. 6G is a partially enlarged cross-sectional view illustrating an example of a manufacturing process of a wiring substrate according to an embodiment of the present invention;

FIG. 6H is a partially enlarged cross-sectional view illustrating an example of a manufacturing process of a wiring substrate according to an embodiment of the present invention;

FIG. 7 is an explanatory diagram illustrating first conductor pads and electrode pads of a wiring substrate according to an embodiment of the present invention; and

FIG. 8 is a partially enlarged cross-sectional view illustrating a wiring substrate of a first modified example a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

A wiring substrate manufactured using a method for manufacturing a wiring substrate according to an embodiment of the present invention is an electronic component built-in wiring substrate having an electronic component therein. In the following, the electronic component built-in wiring substrate is simply referred to as a wiring substrate 100.

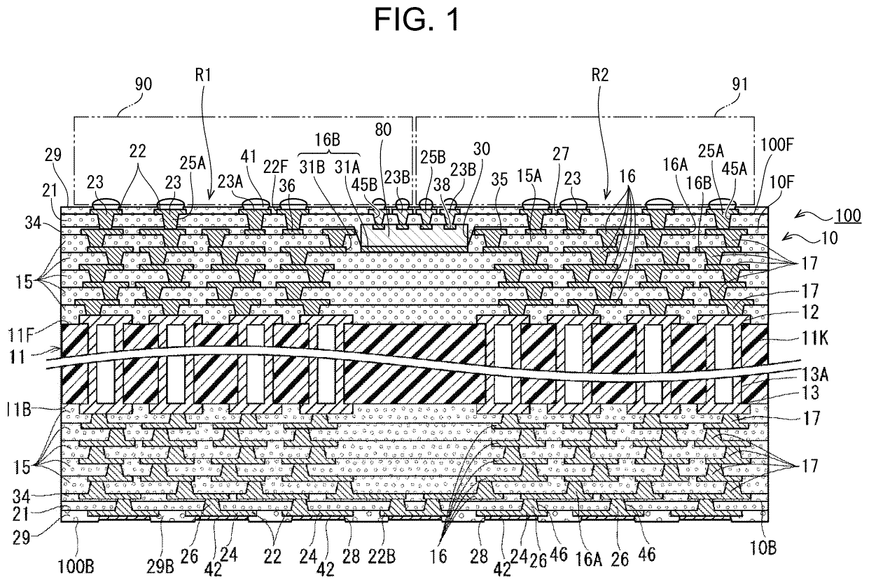

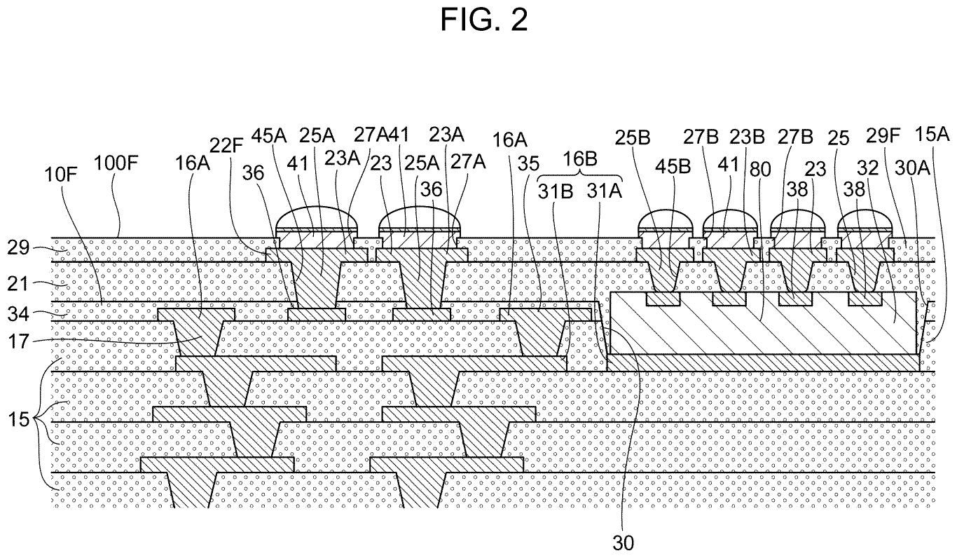

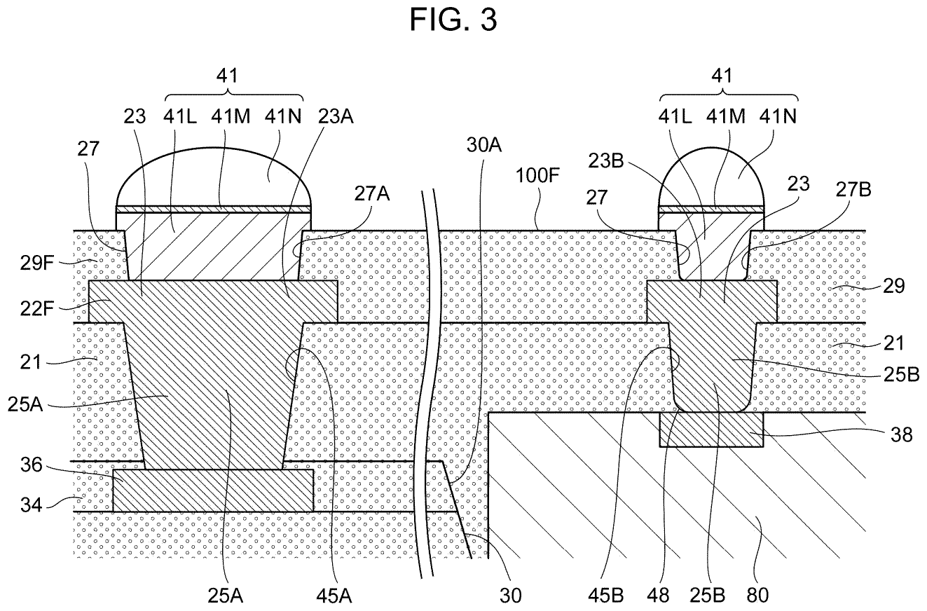

FIG. 1 is a cross-sectional view illustrating the wiring substrate 100 manufactured using the method for manufacturing a wiring substrate of the embodiment of the present disclosure. FIG. 2 is an enlarged cross-sectional view of a part of the wiring substrate 100 illustrated in FIG. 1. FIG. 3 is a further enlarged cross-sectional view of a part of the wiring substrate 100 illustrated in FIG. 2. The wiring substrate 100 is an example of the wiring substrate of the technology of the present disclosure.

Of both sides of the wiring substrate 100 in a thickness direction, an upper surface in FIG. 1 is a first surface (100F), and a lower surface is a second surface (100B). Further, for convenience, the first surface (100F) side may be referred to as an upper side, and the second surface (100B) side may be referred to as a lower side. However, the orientation of the wiring substrate 100 in each drawing does not limit an actual usage state of the wiring substrate 100.

As illustrated in FIG. 1, the wiring substrate 100 has a main body substrate 10. Further, the main body substrate 10 has a core substrate 11, multiple build-up insulating layers 15, and multiple build-up conductor layers 16.

The core substrate 11 is positioned at a center portion of the wiring substrate 100 in the thickness direction. The multiple build-up insulating layers 15 and the multiple build-up conductor layers 16 are laminated on an upper side and a lower side of the core substrate 11.

The core substrate 11 has an insulating base material (11K). In the present embodiment, the insulating base material (11K) is formed of an epoxy resin or a BT (bismaleimide triazine) resin and a reinforcing material such as a glass cloth. An upper surface of the insulating base material (11K) is a first surface (11F) of the core substrate 11, and a lower surface of the insulating base material (11K) is a second surface (11B) of the core substrate 11. As an example, the core substrate 11 has a thickness of 500 μm or more and 1,200 μm or less.

A copper foil (not illustrated) is laminated on the first surface (11F) and the second surface (11B) of the core substrate 11.

Core conductors 12 are formed on the first surface (11F) and the second surface (11B) of the core substrate 11. As an example, the core conductors 12 each have a thickness of 20 μm or more and 50 μm or less.

Multiple through holes (13A) are formed in the insulating base material (11K). The multiple through holes (13A) each penetrate the insulating base material (11K) in the thickness direction. Through-hole conductors 13 are formed on wall surfaces of the through holes (13A) by, for example, copper plating. The core conductors 12 on the first surface (11F) and the core conductors 12 on the second surface (11B) are connected by the through-hole conductors 13.

The multiple build-up insulating layers 15 and the multiple build-up conductor layers 16 are alternately laminated on the first surface (11F) and the second surface (11B) of the core substrate 11. That is, the main body substrate 10 is a multilayer structure in which the multiple build-up insulating layers 15 and the multiple build-up conductor layers 16 are alternately laminated on the first surface (11F) and the second surface (11B) of the core substrate 11.

The build-up insulating layers 15 are each formed of an insulating material. The build-up insulating layers 15 each have a thickness of, for example, 15 μm or more and 35 μm or less.

The build-up conductor layers 16 are each formed of a metal (for example, copper). The build-up conductor layers 16 each have a thickness of, for example, 10 μm or more and 20 μm or less.

Via conductors 17 are formed in the build-up insulating layers 15 closest to the core substrate 11 among the multiple build-up insulating layers 15. The via conductors 17 penetrate these build-up insulating layers 15 in the thickness direction. Among the multiple build-up conductor layers 16, the build-up conductor layers 16 closest to the core substrate 11 are connected to the core conductors 12 by the via conductors 17.

A build-up insulating layer 15 positioned uppermost among the build-up insulating layers 15 laminated on the first surface (11F) of the core substrate 11 is a first build-up insulating layer (15A). The first build-up insulating layer (15A) is an example of an “insulating layer” in the technology of the present disclosure.

A build-up conductor layer 16 positioned uppermost among the build-up conductor layers 16 laminated on the first surface (11F) side of the core substrate 11 is a first build-up conductor layer (16A). The first build-up conductor layer (16A) is formed on the first build-up insulating layer (15A). Further, the first build-up conductor layer (16A) includes an outer conductor circuit layer 35 and first conductor pads 36.

The outer conductor circuit layer 35 is connected to a conductor circuit layer (31B) (to be described later) via the via conductors 17.

As also illustrated in FIGS. 2 and 3, a protective layer 34 is laminated on the first build-up insulating layer (15A). The protective layer 34 covers a portion of the first build-up insulating layer (15A) where the first build-up conductor layer (16A) is not formed and covers the first build-up conductor layer (16A).

The protective layer 34 is formed of, for example, the same material as the build-up insulating layers 15. However, the material of the protective layer 34 is not particularly limited. For example, acrylic resin, epoxy resin, polyimide, or the like, having an elastic modulus of 1 GPa or more and 10 GPa or less can also be used.

The protective layer 34 has a thickness of, for example, 15 μm or more and 25 μm or less, and is thinner than each of the build-up insulating layers 15. As illustrated in FIG. 1, the protective layer 34 forms a first surface (10F), which is an upper surface of the main body substrate 10, and a second surface (10B), which is a lower surface of the main body substrate 10. However, it is also possible that the protective layer 34 is not formed on the second surface (10B) side of the main body substrate 10.

A cavity 30 is formed in the main body substrate 10 on the first surface (10F) side. The cavity 30 is formed penetrating the first build-up insulating layer (15A) and the protective layer 34. The cavity 30 has an opening (30A) (see FIG. 2) on an upper side.

A second build-up conductor layer (16B) positioned second from an outer side among the build-up conductor layers 16 laminated on the first surface (11F) side of the core substrate 11 includes a plane layer (31A) and a conductor circuit layer (31B).

The plane layer (31A) is a layer that is grounded. The plane layer (31A) is positioned on an inner side of the cavity 30. And a bottom surface of the cavity 30 is formed by the plane layer (31A). An adhesive layer (not illustrated) is formed on the plane layer (31A). The plane layer (31A) functions as a mounting pad for stably mounting an electronic component 80 (to be described later).

The conductor circuit layer (31B) is positioned in a portion where the cavity 30 is not formed. The conductor circuit layer (31B) is formed in a predetermined pattern.

The electronic component 80 is accommodated in the cavity 30. The electronic component 80 is fixed onto the plane layer (31A) by an adhesive (not illustrated). By forming the cavity 30, a structure is realized in which the electronic component 80 is arranged in an insulating layer (the first build-up insulating layer (15A)).

Multiple electrode pads 38 are provided on an upper surface of the electronic component 80. The electronic component 80 is accommodated in the cavity 30 with the electrode pads 38 facing upward.

In the illustrated example, upper surfaces of the electrode pads 38 are on the same plane as the upper surface of the electronic component 80, that is, a portion where the electrode pads 38 are not provided. The electrode pads 38 are positioned above the first conductor pads 36 (to be described later).

The multiple first conductor pads 36 are provided on the first build-up insulating layer (15A) on the upper side of the main body substrate 10. The multiple first conductor pads 36 are electrically connected by a circuit layer (not illustrated), and are further electrically connected to other conductor layers, for example, the outer conductor circuit layer 35 and the like. The first conductor pads 36 are included in the first build-up conductor layer (16A). The first conductor pads 36 are an example of conductor pads of the technology of the present disclosure.

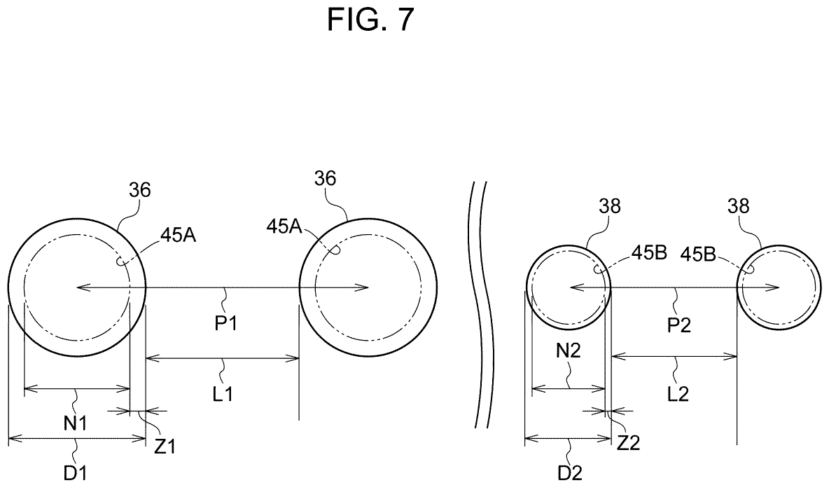

In the technology of the present disclosure, as illustrated in FIG. 7, the first conductor pads 36 each have a circular shape in a plan view. The electrode pads 38 each have a circular shape in a plan view and a smaller diameter than the first conductor pads 36.

An outer build-up insulating layer 21 and an outer build-up conductor layer 22 are laminated on the protective layer 34. The outer build-up insulating layer 21 is an example of an “upper insulating layer” in the technology of the present disclosure.

Multiple first via holes (45A) and multiple second via holes (45B) are formed in outer build-up insulating layer 21. The first via holes (45A) are formed corresponding to the first build-up conductor layer (16A), which includes the first conductor pads 36. The second via holes (45B) are formed corresponding to the electrode pads 38.

As illustrated in FIG. 3, each of the first via holes (45A) is formed in a tapered shape that decreases in diameter toward a bottom part thereof. Further, each of the second via holes (45B) is also formed in a tapered shape that decreases in diameter toward a bottom part thereof. On an inner peripheral surface of the bottom part of each of the second via holes (45B), a curved diameter-reducing portion 48 is formed that is curved so as to decrease in diameter toward an end part on a bottom side (toward the electronic component 80). However, it is also possible to have a structure without the curved diameter-reducing portion 48.

First via conductors (25A) are formed by filling the first via holes (45A) with plating. The bottom parts of the first via conductors (25A) are in contact with the first conductor pads 36. Second via conductors (25B) are formed by filling the second via holes (45B) with plating. The bottom parts of the second via conductors (25B) are in contact with the electrode pads 38.

In the following, regarding the first via holes (45A) and the second via holes (45B), an inner diameter of a bottom part is simply referred to as a “hole diameter.” As illustrated in FIG. 7, a hole diameter (N2) of each of the second via holes (45B) is smaller than a hole diameter (N1) of each of the first via holes (45A). Specifically, the hole diameter (N1) of each of the first via holes (45A) is, for example, 20 μm or more and 40 μm or less, and the hole diameter (N2) of each of the second via holes (45B) is, for example, 10 μm or more and 20 μm or less. Further, a distance (pitch (P1)) between centers of adjacent first via holes (45A) is, for example, 80 μm or more and 100 μm or less, and a distance (pitch (P2)) between centers of adjacent second via holes (45B) is, for example, 30 μm or more and 60 μm or less.

Here, a “residue amount” related to the first conductor pads 36 and the electrode pads 38 is defined. Specifically, the residue amount is a difference in radius between a pad in consideration and the bottom part of a via conductor in contact with this pad. For example, the residue amount (Z1) of each of the first conductor pads 36 is Z1=(D1−N1)/2 when the diameter of each of the first conductor pads 36 is D1 and the hole diameter of each of the first via conductors (25A) is N1. The residue amount (Z2) of each of the electrode pads 38 is Z2=(D2−N2)/2 when the diameter of each of the electrode pads 38 is D2 and the hole diameter of each of the second via conductors (25B) is N2.

In the wiring substrate 100 of the technology of the present disclosure, for the residue amount (Z1) of each of the first conductor pads 36 and the residue amount (Z2) of each of the electrode pads 38, the relationship Z1>Z2 holds.

The wiring substrate 100 of the technology of the present disclosure has the multiple first conductor pads 36 and the multiple electrode pads 38.

Here, an inter-pad distance is defined for each of the multiple first conductor pads 36 and the multiple electrode pads 38. The inter-pad distance is a distance between two pads of the same type in consideration. As illustrated in FIG. 7, in the present embodiment, the first conductor pads 36 and the electrode pads 38 each have a circular shape in a plan view. Therefore, for example, an inter-pad distance (L1) of the first conductor pads 36 is a shortest distance between adjacent first conductor pads 36. An inter-pad distance (L2) of the electrode pads 38 is a shortest distance between adjacent electrode pads 38.

In the wiring substrate 100 of the technology of the present disclosure, for the inter-pad distance (L1) of the first conductor pads 36 and the inter-pad distance (L2) of the electrode pads 38, the relationship L1>L2 holds.

As illustrated in detail in FIG. 2, a first surface plating layer 41 is formed on first outer pads (23A) and second outer pads (23B). The first surface plating layer 41 on the first outer pads (23A) is filled in first openings (27A) and further protrudes above a first surface solder resist layer (29F).

Similar to the first surface plating layer 41 on the first outer pads (23A), the first surface plating layer 41 on the second outer pads (23B) is also filled in second openings (27B) and protrudes above the first surface solder resist layer (29F). These first surface plating layers 41 have substantially the same protrusion height from the first surface solder resist layer (29F).

As illustrated in FIG. 3, the first surface plating layer 41 is formed of electrolytic Cu/Ni/Sn metal layers. A protrusion height of the Cu layer (41L) from the first surface solder resist layer (29F) is 3 μm or more and 20 μm or less. The Ni layer (41M) has a thickness of 2 μm or more and 7 μm or less, and the Sn layer (41N) has a thickness of 5 μm or more and 45 μm or less. In the example illustrated in FIG. 3, the Sn layer (41N) has a curved shape with an upward convex upper surface.

On the first surface (10F) and the second surface (10B) of the main body substrate 10, the outer build-up insulating layer 21 is covered by a solder resist layer 29. Substantially, the solder resist layer 29 forms the first surface (100F) and the second surface (100B) of the wiring substrate 100.

As an example, the solder resist layer 29 has a thickness of 7 μm or more and 25 μm or less, the outer build-up insulating layer 21 has a thickness of 10 μm or more and 20 μm or less, and the outer build-up conductor layer 22 has a thickness of 10 μm or more and 20 μm or less. The thickness of the solder resist layer 29 is defined as a distance from an upper surface of the outer build-up insulating layer 21 to an upper surface of the solder resist layer 29. The thickness of the outer build-up insulating layer 21 is defined as a distance from the upper surface of the protective layer 34 to the upper surface of the outer build-up insulating layer 21. The thickness of each build-up insulating layer 15 is defined as a distance from an upper surface of each build-up insulating layer 15 to an upper surface of the build-up insulating layer 15 formed directly below the each build-up insulating layer 15.

As illustrated in FIG. 2, outer pads 23 are formed on the first surface (10F) of the main body substrate 10. The first surface (100F) of the wiring substrate 100 includes the first surface solder resist layer (29F). Multiple openings 27 are formed in the first surface solder resist layer (29F). The openings 27 expose portions of a first surface outer build-up conductor layer (22F) positioned on the first surface (100F) side among the outer build-up conductor layers 22 as the outer pads 23.

The multiple openings 27 include the first openings (27A) and the second openings (27B). The first openings (27A) expose portions of the first surface outer build-up conductor layer (22F) as the first outer pads (23A), and the second openings (27B) expose portions of the first surface outer build-up conductor layer (22F) as the second outer pads (23B).

Specifically, the outer pads 23 include the first outer pads (23A) and the second outer pads (23B). The first outer pads (23A) are connected to the first conductor pads 36 via the first via conductors (25A). The second outer pads (23B) are connected to the electrode pads 38 via the second via conductors (25B).

As illustrated in FIG. 1, element mounting regions (R1, R2) are formed on the first surface (100F) of the wiring substrate 100. Semiconductor elements (90, 91) are respectively mounted in the element mounting regions (R1, R2). The cavity 30 is arranged at a boundary portion between the element mounting regions (R1, R2) and at a position on an inner side of the wiring substrate 100.

The semiconductor elements (90, 91) are electrically connected via the electrode pads 38, the second via conductors (25B), the second outer pads (23B) and the first surface plating layer 41.

As illustrated in FIG. 1, multiple third openings 28 are formed in a second surface solder resist layer (29B) on the second surface (100B) side of the wiring substrate 100. The third openings 28 expose portions of a second surface outer build-up conductor layer (22B) on the second surface (100B) side as third outer pads 24.

The third outer pads 24 are connected to a first build-up conductor layer (16A) (the build-up conductor layer 16 arranged lowermost) on the second surface (10B) side of the main body substrate 10 via third via conductors 26.

Multiple third via holes 46 are formed in the outer build-up insulating layer 21. The third via conductors 26 are formed by filling the third via holes 46 with plating. The third via holes 46 each have a hole diameter of 20 μm or more and 40 μm or less. A distance (pitch) between adjacent third via holes 46 is 80 μm or more and 100 μm or less. The third via holes 46 are each formed in a tapered shape that becomes thinner toward an upper side.

A second surface plating layer 42 is formed on the third outer pads 24. The second surface plating layer 42 is arranged at bottom parts of the third openings 28. And it is recessed relative to an outer surface of the second surface solder resist layer (29B). The second surface plating layer 42 is formed of electroless Ni/Pd/Au metal layers. A surface treatment of the second surface (100B) is not particularly limited, and may be, for example, a surface treatment in which electroless Ni/Au layers, an OSP film, or the like is formed.

Next, a method for manufacturing the wiring substrate 100 is described.

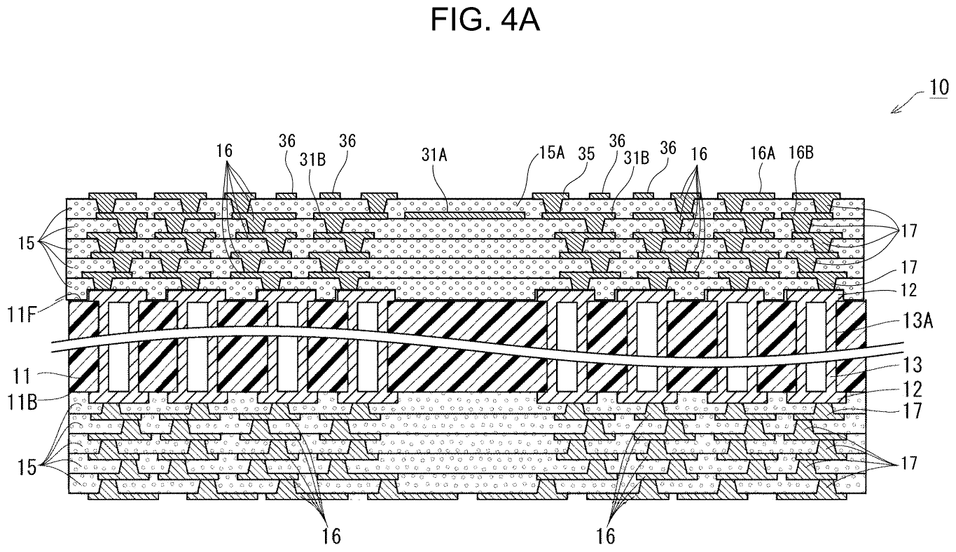

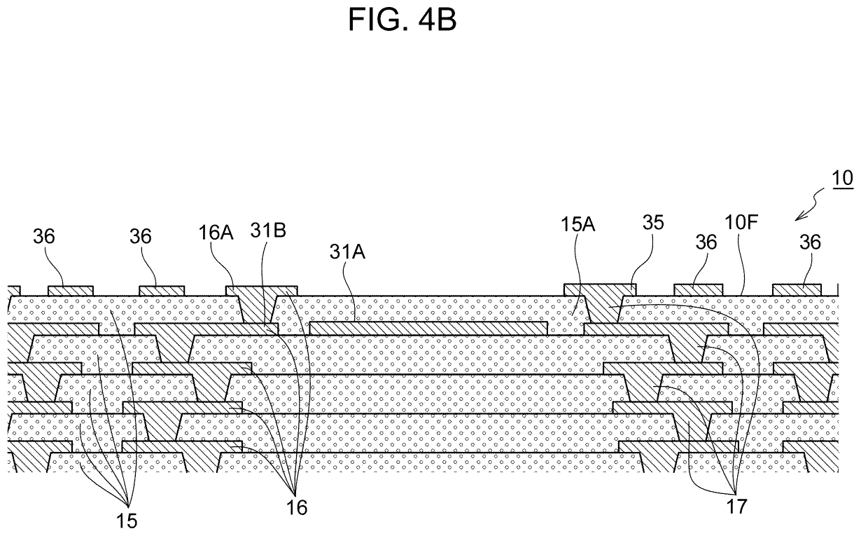

As illustrated in FIGS. 4A and 4B, in the method for manufacturing the wiring substrate 100 according to the technology of the present disclosure, the main body substrate 10 is prepared.

As illustrated in FIG. 4A, in the main body substrate 10, the core conductors 12 are formed on the first surface (11F) and the second surface (11B) of the core substrate 11. Further, the multiple build-up insulating layers 15 and the multiple build-up conductor layers 16 are alternately laminated on the first surface (11F) and the second surface (11B) of the core substrate 11.

The first conductor pads 36 are formed at predetermined positions on the first build-up insulating layer (15A) of the main body substrate 10. The first conductor pads 36 are formed, for example, using a semi-additive method or the like by electroless plating, plating resist processing, electrolytic plating, sputtering, or the like. In the technology of the present disclosure, the first conductor pads 36 are included in the first build-up conductor layer (16A), and, substantially, it is also possible that the first conductor pads 36 are also formed by forming the first build-up conductor layer (16A).

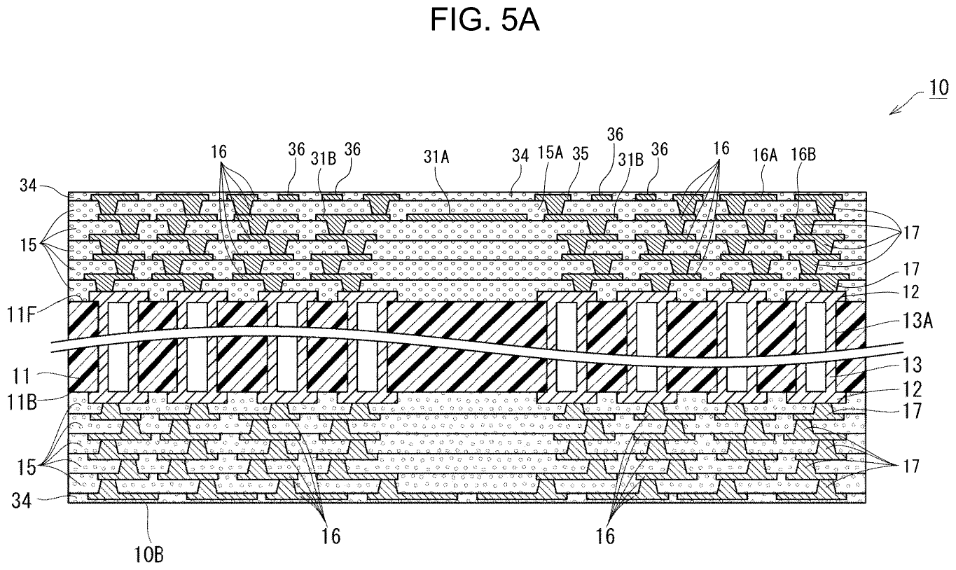

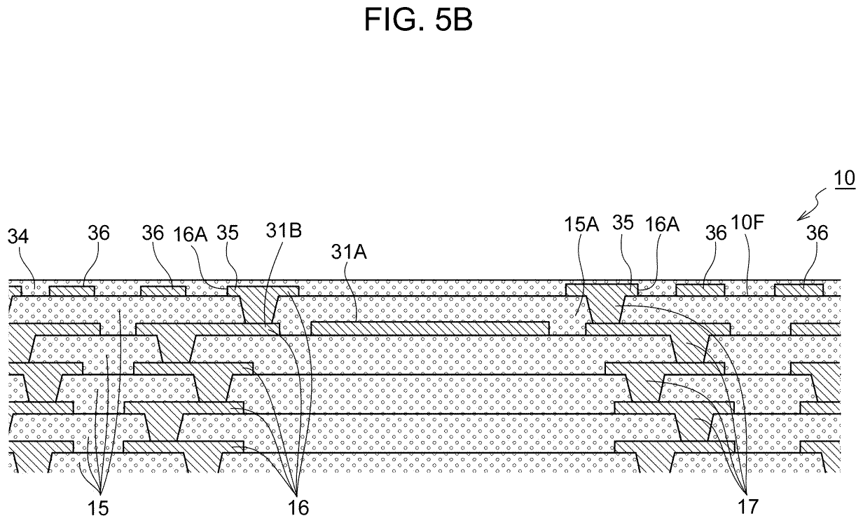

Next, as illustrated in FIGS. 5A and 5B, the protective layer 34 is formed on the first build-up insulating layer (15A) covering the upper surface of the first build-up conductor layer (16A) (including the outer conductor circuit layer 35 and the first conductor pads 36).

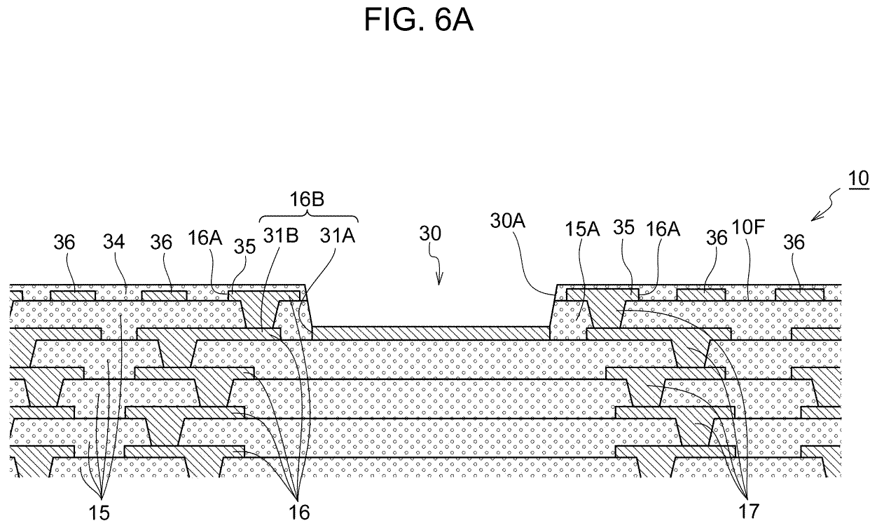

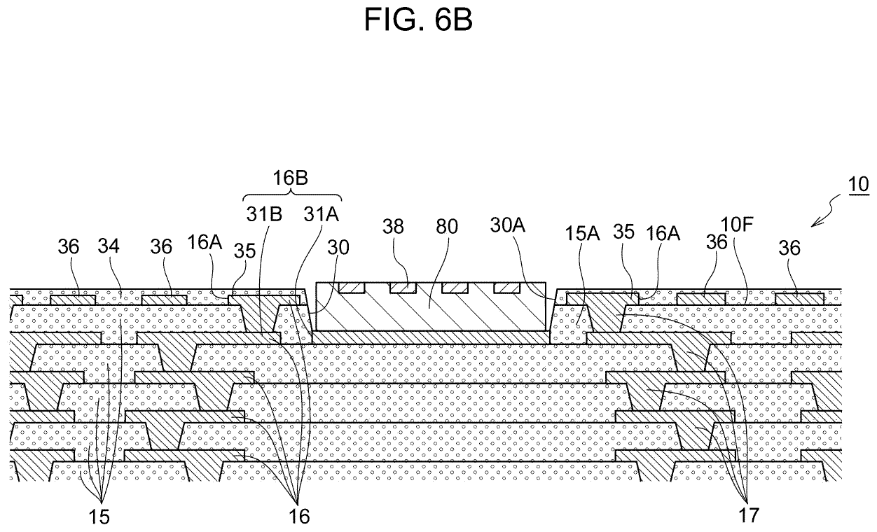

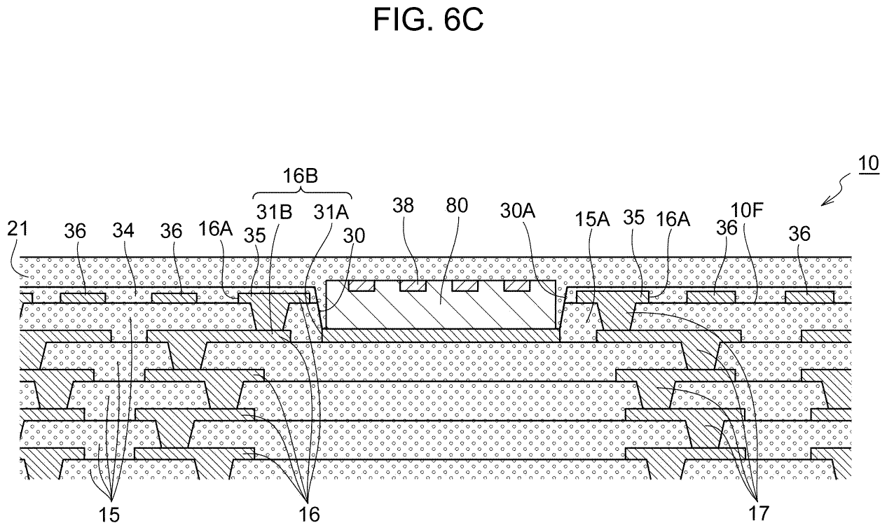

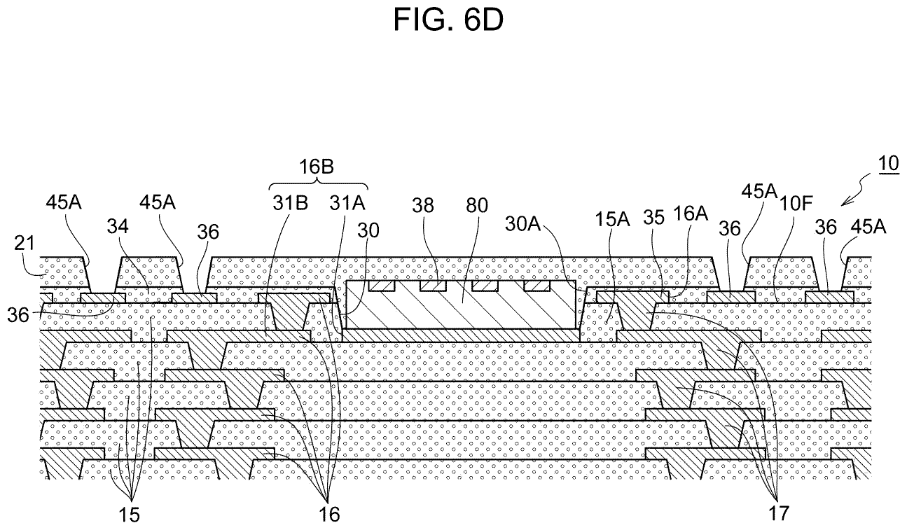

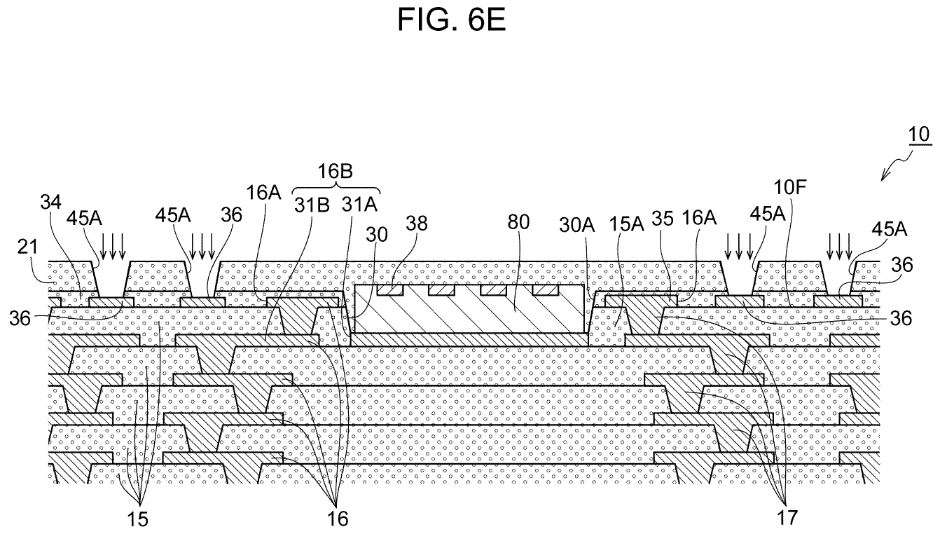

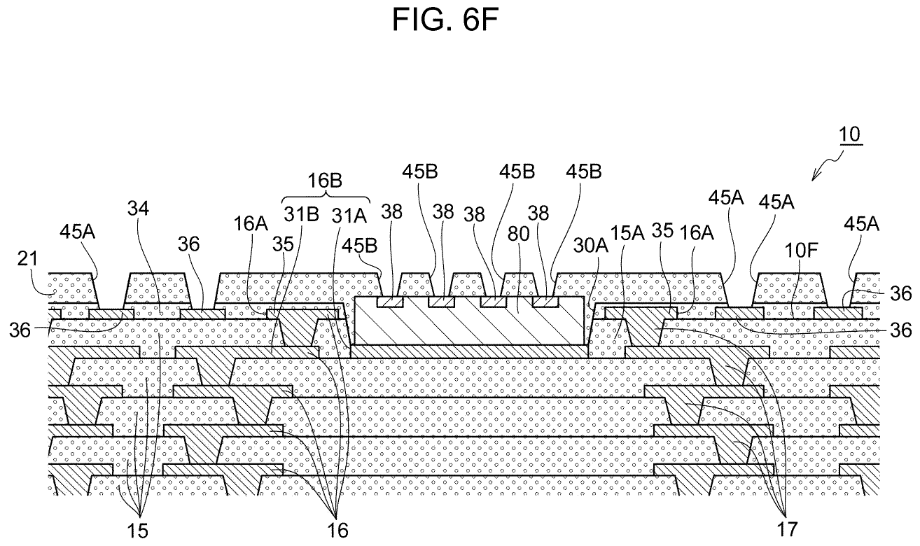

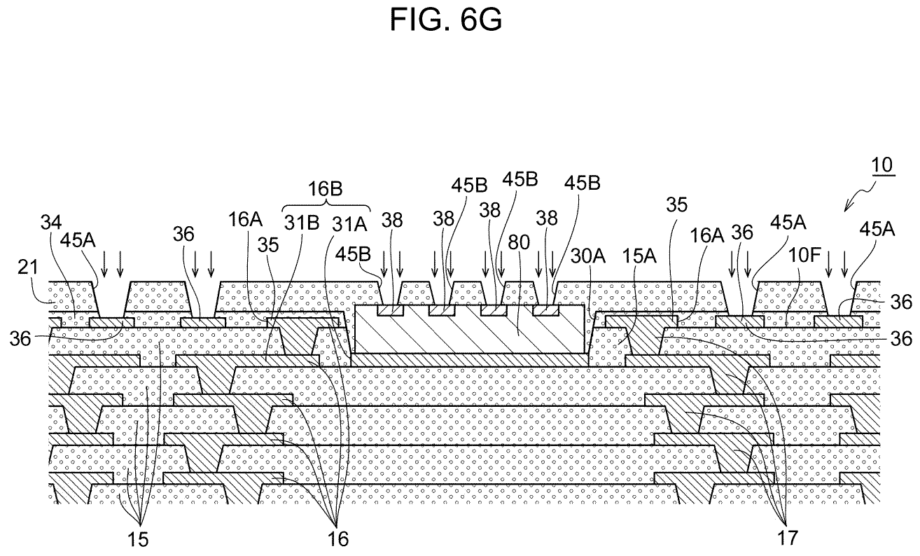

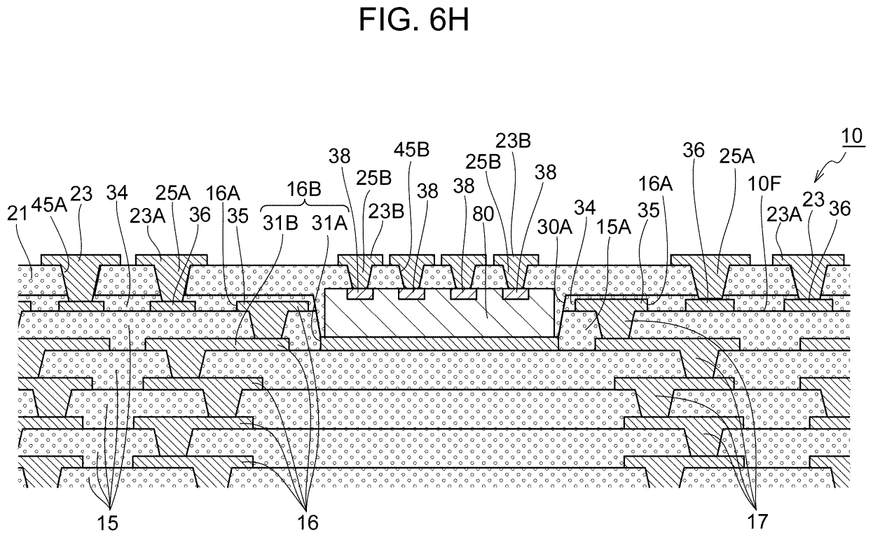

Next, as illustrated in FIG. 6A, the cavity 30 is formed in the protective layer 34 and the first build-up insulating layer (15A). In the technology of the present disclosure, the cavity 30 is formed, for example, by irradiating CO 2 laser to the protective layer 34 and the first build-up insulating layer (15A). By forming the cavity 30 in the protective layer 34 and the first build-up insulating layer (15A), the plane layer (31A) is exposed as the bottom surface of the cavity 30. In the technology of the present disclosure, a range irradiated with the CO₂ laser is the same range as the plane layer (31A). However, for example, the range may be narrower than the plane layer (31A). Further, in the technology of the present disclosure, at this stage, the cavity 30 is formed in a shape that decreases in width toward a bottom part thereof. The plane layer (31A) is exposed at the bottom surface of the cavity 30. The plane layer (31A) is subjected to a desmear treatment. Resin residues generated when the cavity 30 is formed are removed by the desmear treatment. For the desmear treatment, for example, a method such as a wet desmear treatment using an alkaline permanganate solution or a dry desmear treatment using a gas such as plasma can be used. Further, when necessary, an upper surface of the plane layer (31A) is roughened by a roughening treatment.

Next, as illustrated in FIG. 6B, the electronic component 80 is accommodated in the cavity 30. The adhesive layer (not illustrated) is laminated on the plane layer (31A), and the electronic component 80 is adhered to the plane layer (31A) by the adhesive layer. The electronic component 80 is accommodated in the cavity 30 with the electrode pads 38 facing upward. Since the cavity 30 is formed in a shape that decreases in width toward the bottom part, in this state, a gap is formed between a side surface of the electronic component 80 and an inner side surface of the cavity 30.

Next, as illustrated in FIG. 6C, the outer build-up insulating layer 21 is formed covering the upper surface of the protective layer 34 and the upper surface of the electronic component 80 (including the upper surfaces of the electrode pads 38). That is, the outer build-up insulating layer 21 is laminated on the upper surface of the protective layer 34, the upper surface of the electronic component 80, and the upper surfaces of the electrode pads 38. The outer build-up insulating layer 21 is formed, for example, by laminating a film-like epoxy resin onto the protective layer 34 by lamination processing and by applying heat and pressure thereto. A part of the resin of the outer build-up insulating layer 21 enters the gap between the side surface of the electronic component 80 and the inner side surface of the cavity 30. As a result, the gap is filled with the resin. That is, a structure is realized in which a resin is positioned on the side surface of the electronic component 80.

Next, as illustrated in FIG. 6D, the first via holes (45A) are formed in the outer build-up insulating layer 21 and the protective layer 34. In the technology of the present disclosure, the first via holes (45A) are formed by irradiating laser to the outer build-up insulating layer 21 from above.

A wavelength of the laser used in forming the first via holes (45A) is, for example, 1 μm or more and 15 μm or less. In the technology of the present disclosure, CO 2 laser is used in the formation of the first via holes (45A). By forming the first via holes (45A) in the outer build-up insulating layer 21 and the protective layer 34, upper surfaces of the first conductor pads 36 are partially exposed.

Each of the first via holes (45A) has a shape that gradually decreases in inner diameter toward the bottom part thereof, and the bottom part is formed to have a predetermined hole diameter (N1) (see FIG. 7).

Next, as illustrated in FIG. 6E, the first via holes (45A) are subjected to a first desmear treatment for a certain processing time (T1). Resin residues generated due to the formation of the first via holes (45A) are completely or partially removed from the first via holes (45A) by the first desmear treatment. For the first desmear treatment, for example, a method such as a wet desmear treatment using an alkaline permanganate solution or a dry desmear treatment using a gas such as plasma can be used.

Further, when necessary, the first conductor pads 36 are subjected to a roughening treatment, and the upper surfaces of the first conductor pads 36 are roughened.

Next, as illustrated in FIG. 6F, the second via holes (45B) are formed in the outer build-up insulating layer 21. In the technology of the present disclosure, the second via holes (45B) are formed by irradiating laser to the outer build-up insulating layer 21 from above.

A wavelength of the laser used in forming the second via holes (45B) is shorter than the wavelength of the laser used in forming the first via holes (45A). For example, the wavelength of the laser used in forming the second via holes (45B) is 100 nm or more and 500 nm or less. In the technology of the present disclosure, solid laser such as YAG laser is used as ultraviolet laser in the formation of the second via holes (45B). When YAG laser is used, for example, laser with a wavelength of 355 nm can be irradiated. By forming the second via holes (45B) in the outer build-up insulating layer 21, the upper surfaces of the electrode pads 38 are partially exposed.

Each of the second via holes (45B) has a shape that gradually decreases in inner diameter toward the bottom part thereof, and the bottom part is formed to have a predetermined hole diameter (N2) (see FIG. 7). This hole diameter (N2) is smaller than the hole diameter (N1) of the bottom part of each of the first via holes (45A).

In the technology of the present disclosure, the wavelength of the laser used in the formation of the second via holes (45B) is shorter than the wavelength of the laser used in the formation of the first via holes (45A). Therefore, compared to a case where the wavelength of the laser used in the formation of the second via holes (45B) is longer than the wavelength of the laser used in the formation of the first via holes (45A), the second via holes (45B) with a smaller diameter than the first via holes (45A) can be easily formed.

Next, as illustrated in FIG. 6G, the second via holes (45B) are subjected to a second desmear treatment for a certain processing time (T2). Resin residues generated due to the formation of the second via holes (45B) are completely or partially removed from the second via holes (45B) by the second desmear treatment. The second desmear treatment uses the same method as the first desmear treatment. For example, a method such as a wet desmear treatment using an alkaline permanganate solution or a dry desmear treatment using a gas such as plasma is used. In the present embodiment, the processing time (T2) of the second desmear treatment is set shorter than the processing time (T1) of the first desmear treatment.

Further, when necessary, the electrode pads 38 are subjected to a roughening treatment, and the upper surfaces of the electrode pads 38 are roughened.

In this way, when the second via holes (45B) are subjected to the second desmear treatment, substantially, the first via holes (45A) are also subjected to a desmear treatment.

In the technology of the present disclosure, after performing the first desmear treatment, the second via holes (45B) are formed. That is, when the first desmear treatment is performed, the second via holes (45B) are not formed. Therefore, in the first desmear treatment, the second via holes (45B) are not subjected to a desmear treatment.

Then, a total processing time (T3) of the desmear treatments with respect to the first via holes (45A) is T3=T1+T2. When removing resin residues from the first via holes (45A), the total processing time (T3) is set to be a processing time sufficient for removing the resin residues. On the other hand, the desmear treatment for the second via holes (45B) takes the processing time (T2). Therefore, for example, first, the total processing time (T3) of the desmear treatments for the first via holes (45A) and the processing time (T2) of the desmear treatment for the second via holes (45B) are determined. Then, from these processing times, the processing time (T1) of the desmear treatment for the first via holes (45A) can be determined as T1=T3−T2.

Although not illustrated, similarly to that on the first surface (10F), an outer build-up insulating layer 21 is also formed on the second surface (10B) of the main body substrate 10. Then, laser is irradiated to the outer build-up insulating layer 21 on the second surface (10B), and the third via holes 46 are formed.

Next, as illustrated in FIG. 6H, on the first surface (10F) of the main body substrate 10, the first via conductors (25A) are formed in the first via holes (45A), and the second via conductors (25B) are formed in the second via holes (45B). In the technology of the present disclosure, the first via conductors (25A) and the second via conductors (25B) are formed at the same time.

In the following, although not illustrated, on the second surface (10B) of the main body substrate 10, the third via conductors 26 are formed in the third via holes 46. The first via conductors (25A), the second via conductors (25B) and the third via conductors 26 are formed by, for example, electroless plating, plating resist processing, electrolytic plating, or the like.

Further, the outer build-up conductor layers 22 (the first surface outer build-up conductor layer (22F) and the second surface outer build-up conductor layer (22B)) are respectively formed on the outer build-up insulating layers 21.

Further, the first surface solder resist layer (29F) is formed on the first surface (10F) side of the main body substrate 10, and the second surface solder resist layer (29B) is formed on the second surface (10B).

Then, for example, by lithography processing, the first openings (27A) are formed in the first surface solder resist layer (29F), and the third openings 28 are formed in the second surface solder resist layer (29B). The first openings (27A) expose portions of the first surface outer build-up conductor layer (22F) as the first outer pads (23A). The third openings 28 expose portions of the second surface outer build-up conductor layer (22B) as the third outer pads 24.

Further, by ultraviolet laser irradiation, the second openings (27B) are formed in the first surface solder resist layer (29F). The second openings (27B) expose portions of the first surface outer build-up conductor layer (22F) as the second outer pads (23B).

When necessary, the first outer pads (23A), the second outer pads (23B) and the third outer pads 24 are subjected to a desmear treatment.

Next, the first surface solder resist layer (29F) is covered by a resin protective film (not illustrated). Then, electroless plating is performed on the second surface (10B) side of the main body substrate 10, and the second surface plating layer 42 is formed on the third outer pads 24.

Further, the resin protective film covering the first surface solder resist layer (29F) is removed. Further, similarly, the second surface solder resist layer (29B) is covered by a resin protective film (not illustrated).

Then, electrolytic plating is performed on the first surface (10F) side of the main body substrate 10, and the first surface plating layer 41 is formed on the first outer pads (23A) and the second outer pads (23B).

Then, the resin protective film covering the second surface solder resist layer (29B) is removed, and the wiring substrate 100 is completed.

Next, effects of the present embodiment are described.

In the wiring substrate 100 of the technology of the present disclosure, the first via holes (45A) and the second via holes (45B) are formed in the outer build-up insulating layer 21. Then, by subjecting the first via holes (45A) and the second via holes (45B) to a desmear treatment, resin residues are completely or partially removed from the first via holes (45A) and the second via holes (45B).

Here, for comparison, a case is assumed where the first via holes (45A) and the second via holes (45B) are subjected to a desmear treatment for the same processing time. For example, a case is assumed where the first via holes (45A) and the second via holes (45B) are subjected to a desmear treatment at the same time.

In this case, since the hole diameter (N1) of each of the first via holes (45A) is larger than the hole diameter (N2) of each of the second via holes (45B), when both the first via holes (45A) and the second via holes (45B) are subjected to a desmear treatment for the same processing time, the processing time is set to the processing time for the first via holes (45A). That is, the second via holes (45B) each having a relatively small hole diameter are subjected to a desmear treatment for a longer time than necessary.

When the second via holes (45B) are subjected to a desmear treatment for a longer time than necessary, haloing is likely to occur between the electrode pads 38 and the outer build-up insulating layer 21 on an upper side of the electrode pads 38. That is, the outer build-up insulating layer 21 is likely to peel off from the electrode pads 38. In particular, in the technology of the present disclosure, the outer build-up insulating layer 21 contains resin. When the resin melts due to the desmear treatment for the second via holes (45B), it is likely to cause the outer build-up insulating layer 21 to peel off from the electrode pads 38.

Then, there is a risk that a peeled portion may spread between the outer build-up insulating layer 21 and the electronic component 80. In particular, as in the technology of the present disclosure, when the inter-pad distance (L2) of the electrode pads 38 is relatively short compared to the inter-pad distance (L1) of the first conductor pads 36, the outer build-up insulating layer 21 is likely to peel off from the electronic component 80 in a portion between the multiple electrode pads 38.

Therefore, in the technology of the present disclosure, the processing time (T2) of the desmear treatment for the second via holes (45B) is shorter than the total processing time (T3) of the desmear treatments for the first via holes (45A). Therefore, compared to the case where the first via holes (45A) and the second via holes (45B) are subjected to a desmear treatment for the same processing time, haloing between the electrode pads 38 and the outer build-up insulating layer 21 above the electrode pads 38 can be suppressed.

In particular, in the wiring substrate 100 of the technology of the present disclosure, as illustrated in FIG. 7, for the residue amount (Z1) of each of the first conductor pads 36 and the residue amount (Z2) of each of the electrode pads 38, the relationship Z1>Z2 holds. In this way, when the residue amount (Z2) is relatively short, compared to a case where the relationship Z1<Z2 holds between the residual amounts (Z1, Z2), peeling due to haloing between the electrode pads 38 and the outer build-up insulating layer 21 is likely to occur. However, in the technology of the present disclosure, the processing time (T2) of the desmear treatment for the second via holes (45B) is shorter than the total processing time (T3) of the desmear treatments for the first via holes (45A). Therefore, occurrence of peeling between the electrode pads 38 and the outer build-up insulating layer 21 due to haloing can be suppressed.

Further, in the wiring substrate 100 of the technology of the present disclosure, for the inter-pad distance (L1) of the first conductor pads 36 and the inter-pad distance (L2) of the electrode pads 38, the relationship L1>L2 holds. In this way, when the inter-pad distance (L2) is relatively short, compared to a case where the relationship L1<L2 holds between the inter-pad distances (L1, L2), peeling of the outer build-up insulating layer 21 from the electronic component 80 is likely to occur. However, in the technology of the present disclosure, since the processing time (T2) of the desmear treatment for the second via holes (45B) is shorter than the processing time (T3) of the desmear treatments for the first via holes (45A), occurrence of peeling due to haloing between the electronic component 80 and the outer build-up insulating layer 21 can be suppressed.

In the above, the processing time (T2) of the desmear treatment for the second via holes (45B) is set shorter than the processing time (T1) of the desmear treatment for the first via holes (45A). That is, T1>T2. However, since the total processing time (T3) of the desmear treatments for the first via holes (45A) is T3=T1+T2, for example, even when T1<T2, a state in which T3>T2 can be realized. As in the technology of the present disclosure, by setting T1>T2, a state in which T3 is sufficiently longer than T2 can be realized.

In any case, the processing time (T1) of the first desmear treatment and the processing time (T2) of the second desmear treatment can be set, for example, as predetermined processing times.

In the above, the laser used in the formation of the second via holes (45B) is ultraviolet light. However, it may be visible light as long as it has a shorter wavelength than that of the laser used in the formation of the first via holes (45A).

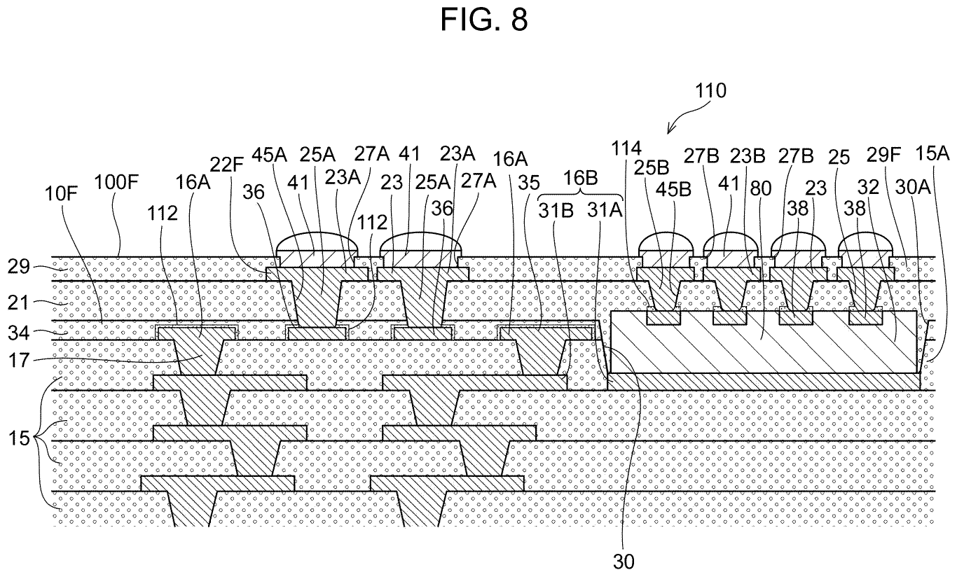

In the first embodiment, it is also possible to have a structure of a wiring substrate 110 of a first modified example illustrated in FIG. 8.

In the wiring substrate 110 of the first modified example, coating films (112, 114) are formed on the surfaces of the outer conductor circuit layer 35, the first conductor pads 36 and the electrode pads 38. Specifically, the coating film 112 covers the surfaces of the outer conductor circuit layer 35 and the first conductor pads 36 that face the protective layer 34. The coating film 114 covers the surfaces of the electrode pads 38 that face the outer build-up insulating layer 21. The coating film 112 may be formed only on portions of the surfaces of the outer conductor circuit layer 35 and the first conductor pads 36 that face the protective layer 34. The coating film 114 may be formed only on portions of the surfaces of the electrode pads 38 that face the outer build-up insulating layer 21.

The coating film 112 increases adhesion between the outer conductor circuit layer 35 and first conductor pads 36 and the protective layer 34. The coating film 112 is formed of, for example, a material that can bind to both an organic material such as a resin that forms the protective layer 34 and an inorganic material such as a metal that forms the outer conductor circuit layer 35 and the first conductor pads 36. The coating film 114 increases adhesion between the electrode pads 38 and the outer build-up insulating layer 21. The coating film 114 is formed of, for example, a material that can bind to both an organic material such as a resin that forms the outer build-up insulating layer 21 and an inorganic material such as a metal that forms the electrode pads 38.

The coating films (112, 114) are formed of, for example, a material that contains both a reactive group capable of chemically bonding to an organic material and a reactive group capable of chemically bonding to an inorganic material. An example of a material of the coating films (112, 114) is a silane coupling agent containing an azole silane compound such as a triazole compound.

The material of the coating film 112 may be any material that can increase the adhesion strength between the outer conductor circuit layer 35 and first conductor pads 36 and the protective layer 34, compared to the case where the protective layer 34 is directly formed on the outer conductor circuit layer 35 and first conductor pads 36. Further, the material of the coating film 114 may be any material that can increase the adhesion strength between the electrode pads 38 and the outer build-up insulating layer 21, compared to the case where the outer build-up insulating layer 21 is directly formed on the electrode pads 38. Therefore, the coating films (112, 114) are not limited to silane coupling agents. Compared to the case where the protective layer 34 is directly formed on the outer conductor circuit layer 35 and the first conductor pads 36, the outer conductor circuit layer 35 and the first conductor pads 36 adhere to the protective layer 34 with high strength due to the coating film 112. Further, compared to the case where the outer build-up insulating layer 21 is directly formed on the electrode pads 38, the electrode pads 38 adhere to the outer build-up insulating layer 21 with high strength due to the coating film 114.

In the method for manufacturing the wiring substrate 110 of the first modified example, the coating film 112 is formed, for example, after the first conductor pads 36 are formed on the first build-up insulating layer (15A) (see FIGS. 4A and 4B) and before the protective layer 34 is formed (see FIGS. 5A and 5B). Then, when the first via holes (45A) are formed in the outer build-up insulating layer 21 and the protective layer 34, portions of the coating film 112 corresponding to the first via holes (45A) are removed.

The coating film 114 is formed, for example, after the electronic component 80 is accommodated in the cavity 30 (see FIG. 6B) and before the outer build-up insulating layer 21 is formed (see FIG. 6C). Then, when the second via holes (45B) are formed in the outer build-up insulating layer 21, portions of the coating film 114 corresponding to the second via holes (45B) are removed.

The electronic component in the technology of the present disclosure may be a semiconductor element or may be a passive element such as a chip capacitor, an inductor, or a resistor.

In the technology of the present disclosure, by forming the cavity 30, a structure is realized in which an electronic component is arranged in an insulating layer. Instead of this, for example, an electronic component may be arranged on an insulating layer without forming the cavity 30 in the insulating layer.

The wiring substrate of the technology of the present disclosure is not limited to those having the structures illustrated in the drawings and those having the structures, shapes, and materials exemplified in the present specification. As described above, the wiring substrate of the embodiment can have any laminated structure. For example, the wiring substrate of the embodiment may be a coreless substrate that does not include a core substrate. The wiring substrate of the embodiment can include any number of conductor layers and any number of insulating layers.

The method for manufacturing the wiring substrate of the technology of the present disclosure is not limited to the method described with reference to the drawings. For example, the conductor layers may be formed using a full additive method. The insulating layers can each be formed using a resin in any form without being limited to a film-like resin. In the method for manufacturing the wiring substrate of the embodiment, it is also possible that any process other than the processes described above is added, or some of the processes described above are omitted.

Japanese Patent Application Laid-Open Publication No. 2016-58472 describes a method for manufacturing a wiring substrate, which includes: a main body substrate accommodating an interposer in a cavity; an outer build-up insulating layer formed on the main body substrate and the interposer; and via conductors formed in via formation holes penetrating the outer build-up insulating layer. In the method for manufacturing the wiring substrate, the via formation holes include first via formation holes that are arranged on an outer side of the cavity when viewed from a thickness direction and second via formation holes that expose electrode terminals of the interposer and each have a smaller diameter than each of the first via formation holes. The first via formation holes are formed by laser processing, and the second via formation holes are formed using laser with a shorter wavelength than the laser used in forming the first via formation holes.

When manufacturing a wiring substrate with a structure in which multiple conductor pads formed on an insulating layer are further covered with an upper insulating layer, via holes for providing conductor vias in contact with a conductor layer are formed in the upper insulating layer. Then, after the formation of the via holes, a desmear treatment is performed to remove resin residues in the via holes. In the desmear treatment, a gap occurring between the conductor layer and the upper insulating layer may expand to between the insulating layer and the upper insulating layer, and the upper insulating layer may peel off from the insulating layer. In particular, in a wiring substrates having multiple conductor pads with different inter-pad distances, peeling is likely to occur in a portion where a distance between conductor layers is relatively short.

A method for manufacturing a wiring substrate according to an embodiment of the present invention includes: forming multiple conductor pads on an upper surface of an insulating layer; arranging an electronic component having multiple electrode pads on the insulating layer or in the insulating layer with the electrode pads facing upward, the electrode pads having an inter-pad distance shorter than an inter-pad distance of the conductor pads; forming an upper insulating layer covering the upper surface of the insulating layer, the conductor pads and the electronic component; forming, in the upper insulating layer, first via holes exposing the conductor pads; performing a first desmear treatment to remove residues from the first via holes; forming, in the upper insulating layer, second via holes exposing the electrode pads; performing a second desmear treatment to remove residues from the second via holes; forming first via conductors in the first via holes; and forming second via conductors in the second via holes, wherein the forming of the second via holes is performed after the performing of the first desmear treatment.

According to an embodiment of the present invention, when manufacturing a wiring substrate with a structure in which multiple conductor pads are formed on an insulating layer and the multiple conductor pads are covered with an upper insulating layer, even in a portion where an inter-pad distance of the conductor pads is short, peeling of the upper insulating layer can be suppressed.

Obviously, numerous modifications and variations of the present invention are possible in light of the above teachings. It is therefore to be understood that within the scope of the appended claims, the invention may be practiced otherwise than as specifically described herein.

1. A method for manufacturing a wiring substrate, comprising:
forming a plurality of conductor pads on a surface of an insulating layer;
positioning, on or in the insulating layer, an electronic component having a plurality of electrode pads;
forming a second insulating layer on the insulating layer such that the second insulating layer covers the surface of the insulating layer, the conductor pads and the electronic component;
forming a plurality of first via holes in the second insulating layer such that the first via holes expose the conductor pads formed on the surface of the insulating layer, respectively;
applying a first desmear treatment to the second insulating layer such that residues are removed from the first via holes formed in the second insulating layer;
forming a plurality of second via holes in the second insulating layer after the first desmear treatment such that the second via holes expose the electrode pads of the electronic component positioned on or in the insulating layer, respectively;
applying a second desmear treatment to the second insulating layer such that residues are removed from the second via holes formed in the second insulating layer;
forming a plurality of first via conductors in the first via holes formed in the second insulating layer, respectively; and
forming a plurality of second via conductors in the second via holes formed in the second insulating layer, respectively.

2. The method of claim 1, wherein the second desmear treatment is applied such that a processing time of the second desmear treatment is shorter than a processing time of the first desmear treatment.

3. The method of claim 1, wherein the first via conductors and the second via conductors are formed in the first via holes and the second via conductors in a same process.

4. The method of claim 1, further comprising:
forming a coating film on the plurality of conductor pads and the plurality of electrode pads such that the coating film covers surfaces of the conductor pads and the electrode pads.

5. The method of claim 1, wherein the forming of the first via holes includes irradiating laser upon the second insulating layer such that irradiation of the laser forms the first via holes in the second insulating layer, and the forming of the second via holes includes irradiating laser upon the second insulating layer at a wavelength that is shorter than a wavelength of the laser for the forming of the first via holes such that the irradiation of the laser forms the second via holes in the second insulating layer.

6. The method of claim 1, wherein the electrode pads of the electronic component have an inter-pad distance that is shorter than an inter-pad distance of the conductor pads formed on the surface of the insulating layer.

7. The method of claim 2, wherein the first via conductors and the second via conductors are formed in the first via holes and the second via conductors in a same process.

8. The method of claim 2, further comprising:
forming a coating film on the plurality of conductor pads and the plurality of electrode pads such that the coating film covers surfaces of the conductor pads and the electrode pads.

9. The method of claim 2, wherein the forming of the first via holes includes irradiating laser upon the second insulating layer such that irradiation of the laser forms the first via holes in the second insulating layer, and the forming of the second via holes includes irradiating laser upon the second insulating layer at a wavelength that is shorter than a wavelength of the laser for the forming of the first via holes such that the irradiation of the laser forms the second via holes in the second insulating layer.

10. The method of claim 2, wherein the electrode pads of the electronic component have an inter-pad distance that is shorter than an inter-pad distance of the conductor pads formed on the surface of the insulating layer.

11. The method of claim 3, further comprising:
forming a coating film on the plurality of conductor pads and the plurality of electrode pads such that the coating film covers surfaces of the conductor pads and the electrode pads.

12. The method of claim 3, wherein the forming of the first via holes includes irradiating laser upon the second insulating layer such that irradiation of the laser forms the first via holes in the second insulating layer, and the forming of the second via holes includes irradiating laser upon the second insulating layer at a wavelength that is shorter than a wavelength of the laser for the forming of the first via holes such that the irradiation of the laser forms the second via holes in the second insulating layer.

13. The method of claim 3, wherein the electrode pads of the electronic component have an inter-pad distance that is shorter than an inter-pad distance of the conductor pads formed on the surface of the insulating layer.

14. The method of claim 4, wherein the forming of the first via holes includes irradiating laser upon the second insulating layer such that irradiation of the laser forms the first via holes in the second insulating layer, and the forming of the second via holes includes irradiating laser upon the second insulating layer at a wavelength that is shorter than a wavelength of the laser for the forming of the first via holes such that the irradiation of the laser forms the second via holes in the second insulating layer.

15. The method of claim 4, wherein the electrode pads of the electronic component have an inter-pad distance that is shorter than an inter-pad distance of the conductor pads formed on the surface of the insulating layer.

16. The method of claim 5, wherein the electrode pads of the electronic component have an inter-pad distance that is shorter than an inter-pad distance of the conductor pads formed on the surface of the insulating layer.

17. The method of claim 7, further comprising:
forming a coating film on the plurality of conductor pads and the plurality of electrode pads such that the coating film covers surfaces of the conductor pads and the electrode pads.

18. The method of claim 7, wherein the forming of the first via holes includes irradiating laser upon the second insulating layer such that irradiation of the laser forms the first via holes in the second insulating layer, and the forming of the second via holes includes irradiating laser upon the second insulating layer at a wavelength that is shorter than a wavelength of the laser for the forming of the first via holes such that the irradiation of the laser forms the second via holes in the second insulating layer.

19. The method of claim 7, wherein the electrode pads of the electronic component have an inter-pad distance that is shorter than an inter-pad distance of the conductor pads formed on the surface of the insulating layer.

20. The method of claim 8, wherein the forming of the first via holes includes irradiating laser upon the second insulating layer such that irradiation of the laser forms the first via holes in the second insulating layer, and the forming of the second via holes includes irradiating laser upon the second insulating layer at a wavelength that is shorter than a wavelength of the laser for the forming of the first via holes such that the irradiation of the laser forms the second via holes in the second insulating layer.
